(19) United States
(12) Patent Application Publication
(10) Pub. No.: US 2025/0279800 A1
(43) Pub. Date: Sep. 4, 2025

(54) SWITCHING TECHNIQUE FOR SUPPLY-SIDE HARMONIC TUNING IN A VOLTAGE-CONTROLLED OSCILLATOR (VCO)

(71) Applicant: QUALCOMM Incorporated, San Diego, CA (US)

(72) Inventors: Aaron CURRY, Long Beach, CA (US); Payam LAJEVARDI, Sunnyvale, CA (US); Emanuele LOPELLI, Laguna Niguel, CA (US); Shen WANG, Saratoga, CA (US)

(21) Appl. No.: 18/591,195

(22) Filed: Feb. 29, 2024

(51) Int. Cl. H04B 1/403; H03B 5/12

(52) U.S. Cl. CPC H04B 1/403; H03B 5/1212

(57) ABSTRACT

Certain aspects of the present disclosure are directed towards techniques and apparatus for oscillating signal generation. An example apparatus generally includes a VCO and a first filter coupled to the VCO, wherein the first filter comprises: a first inductive element including a first terminal coupled to the voltage rail and a second terminal coupled to the VCO, a first capacitor bank coupled between the second terminal of the first inductive element and a reference potential node, and a bypass capacitive element coupled between the first terminal of the first inductive element and the reference potential node.

### TECHNICAL FIELD

Certain aspects of the present disclosure generally relate to electronic circuits and, more particularly, to techniques for harmonic tuning for a voltage-controlled oscillator (VCO).

### BACKGROUND

Wireless communication devices are widely deployed to provide various communication services such as telephony, video, data, messaging, broadcasts, and so on. Such wireless communication devices may transmit and/or receive radio frequency (RF) signals via any of various suitable radio access technologies (RATs) including, but not limited to, Fifth Generation (5G) New Radio (NR), Long Term Evolution (LTE), Code Division Multiple Access (CDMA), Time Division Multiple Access (TDMA), Wideband CDMA (WCDMA), Global System for Mobility (GSM), Bluetooth, Bluetooth Low Energy (BLE), ZigBee, wireless local area network (WLAN) RATs (e.g., WiFi), and the like.

A wireless communication network may include a number of base stations that can support communication for a number of mobile stations. A mobile station (MS) may communicate with a base station (BS) via a downlink and an uplink. The downlink (or forward link) refers to the communication link from the base station to the mobile station, and the uplink (or reverse link) refers to the communication link from the mobile station to the base station. A base station may transmit data and control information on the downlink to a mobile station and/or may receive data and control information on the uplink from the mobile station. The base station and/or mobile station may include one or more frequency synthesizers implemented with voltage-controlled oscillators (VCOs).

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide advantages that include increased filter quality factor for a voltage-controlled oscillator (VCO).

Certain aspects of the present disclosure are directed towards an apparatus for oscillating signal generation. The apparatus generally includes a VCO and a first filter coupled to the VCO, wherein the first filter comprises: a first inductive element including a first terminal coupled to a voltage rail and a second terminal coupled to the VCO; a first capacitor bank coupled between the second terminal of the first inductive element and a reference potential node; and a bypass capacitive element coupled between the first terminal of the first inductive element and the reference potential node.

Certain aspects of the present disclosure are directed towards a method for oscillating signal generation. The method generally includes: configuring a first capacitor bank of a first filter based on an oscillating frequency of a VCO, wherein at least a portion of the first filter is coupled between a voltage rail and the VCO, the first filter comprising: a first inductive element including a first terminal coupled to the voltage rail and a second terminal coupled to the VCO, wherein the first capacitor bank is coupled between the second terminal of the first inductive element and a reference potential node; and a bypass capacitive element coupled between the first terminal of the first inductive element and the reference potential node. The method may further include generating an oscillating signal with the oscillating frequency via the VCO.

Certain aspects of the present disclosure are directed towards a wireless device. The wireless device generally includes: one or more antennas; a transmitter or a receiver coupled to the one or more antennas and including a frequency synthesizer, wherein the frequency synthesizer includes a VCO; and a filter coupled to the VCO, wherein the filter comprises: a inductive element including a first terminal coupled to a voltage rail and a second terminal coupled to the VCO; a capacitor bank coupled between the second terminal and a reference potential node; and a bypass capacitive element coupled between the first terminal of the inductive element and the reference potential node.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a diagram of an example wireless communications network, in which aspects of the present disclosure may be practiced.

FIG. 2 is a block diagram conceptually illustrating a design of an example base station (BS) and user equipment (UE), in which aspects of the present disclosure may be practiced.

FIG. 3 is a block diagram of an example radio frequency (RF) transceiver, in which aspects of the present disclosure may be practiced.

FIG. 4 illustrates an example oscillating circuit including a voltage-controlled oscillator (VCO), in accordance with certain aspects of the present disclosure.

FIG. 5 illustrates example implementations of filters for a VCO, in accordance with certain aspects of the present disclosure.

FIG. 6 is a flow diagram illustrating example operations for oscillating signal generation, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure are directed toward a filter for a voltage-controlled oscillator (VCO). The filter may include a capacitor bank including capacitive elements selectively coupled in parallel using respective switches. The filter may be a supply-side filter of the VCO and configured to use one or more n-type metal-oxide-semiconductor (NMOS) transistors to implement the switches for the capacitor bank. Using NMOS transistors increases the quality factor (Q) of the filter as compared to implementations that use p-type metal-oxide-semiconductor (PMOS) transistors for the supply-side filter.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example Wireless System

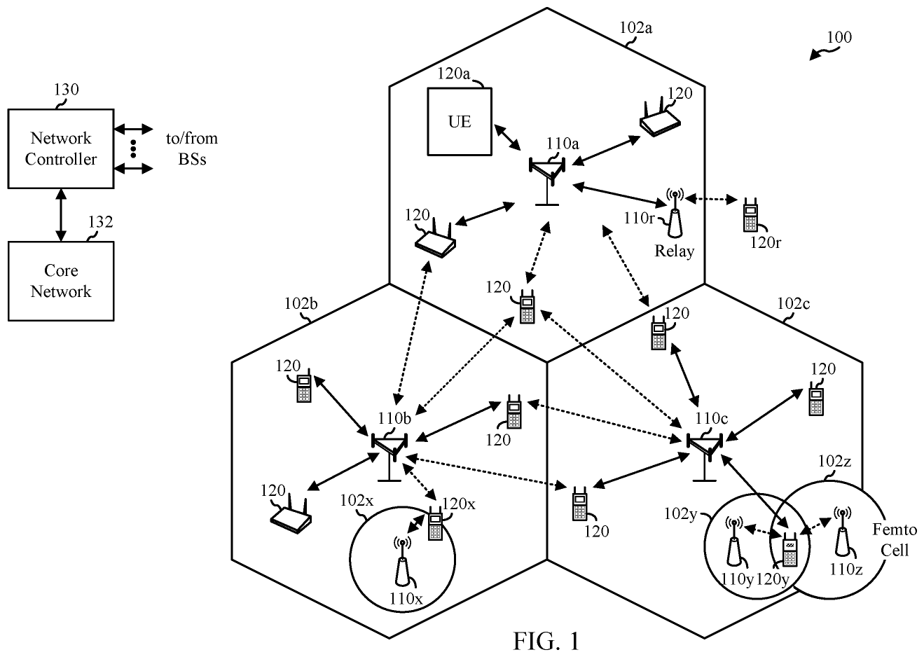

FIG. 1 illustrates an example wireless communications network 100, in which aspects of the present disclosure may be practiced. For example, the wireless communications network 100 may be a New Radio (NR) system (e.g., a Fifth Generation (5G) NR network), an Evolved Universal Terrestrial Radio Access (E-UTRA) system (e.g., a Fourth Generation (4G) network), a Universal Mobile Telecommunications System (UMTS) (e.g., a Second Generation/Third Generation (2G/3G) network), or a code division multiple access (CDMA) system (e.g., a 2G/3G network), or may be configured for communications according to an IEEE standard such as one or more of the 802.11 standards, etc.

As illustrated in FIG. 1, the wireless communications network 100 may include a number of base stations (BSs) 110a-z (each also individually referred to herein as “BS 110” or collectively as “BSs 110”) and other network entities. A BS may also be referred to as an access point (AP), an evolved Node B (eNodeB or eNB), a next generation Node B (gNodeB or gNB), or some other terminology.

A BS 110 may provide communication coverage for a particular geographic area, sometimes referred to as a “cell,” which may be stationary or may move according to the location of a mobile BS. In some examples, the BSs 110 may be interconnected to one another and/or to one or more other BSs or network nodes (not shown) in wireless communications network 100 through various types of backhaul interfaces (e.g., a direct physical connection, a wireless connection, a virtual network, or the like) using any suitable transport network. In the example shown in FIG. 1, the BSs 110a, 110b, and 110c may be macro BSs for the macro cells 102a, 102b, and 102c, respectively. The BS 110x may be a pico BS for a pico cell 102x. The BSs 110y and 110z may be femto BSs for the femto cells 102y and 102z, respectively. A BS may support one or multiple cells.

The BSs 110 communicate with one or more user equipment's (UEs) 120a-y (each also individually referred to herein as “UE 120” or collectively as “UEs 120”) in the wireless communications network 100. A UE may be fixed or mobile and may also be referred to as a user terminal (UT), a mobile station (MS), an access terminal, a station (STA), a client, a wireless device, a mobile device, or some other terminology. A user terminal may be a wireless device, such as a cellular phone, a smartphone, a personal digital assistant (PDA), a handheld device, a wearable device, a wireless modem, a laptop computer, a tablet, a personal computer, etc.

The BSs 110 are considered transmitting entities for the downlink and receiving entities for the uplink. The UEs 120 are considered transmitting entities for the uplink and receiving entities for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink. Nᵤₚ UEs may be selected for simultaneous transmission on the uplink, N_{dn} UEs may be selected for simultaneous transmission on the downlink. Nᵤₚ may or may not be equal to Nan, and Nᵤₚ and N_{dn} may be static values or can change for each scheduling interval. Beam-steering or some other spatial processing technique may be used at the BSs 110 and/or UEs 120.

The UEs 120 (e.g., 120x, 120y, etc.) may be dispersed throughout the wireless communications network 100, and each UE 120 may be stationary or mobile. The wireless communications network 100 may also include relay stations (e.g., relay station 110r), also referred to as relays or the like, that receive a transmission of data and/or other information from an upstream station (e.g., a BS 110a or a UE 120r) and send a transmission of the data and/or other information to a downstream station (e.g., a UE 120 or a BS 110), or that relays transmissions between UEs 120, to facilitate communication between devices.

The BSs 110 may communicate with one or more UEs 120 at any given moment on the downlink and uplink. The downlink (i.e., forward link) is the communication link from the BSs 110 to the UEs 120, and the uplink (i.e., reverse link) is the communication link from the UEs 120 to the BSs 110. A UE 120 may also communicate peer-to-peer with another UE 120.

The wireless communications network 100 may use multiple transmit and multiple receive antennas for data transmission on the downlink and uplink. BSs 110 may be equipped with a number Nₐₚ of antennas to achieve transmit diversity for downlink transmissions and/or receive diversity for uplink transmissions. A set Nᵤ of UEs 120 may receive downlink transmissions and transmit uplink transmissions. Each UE 120 may transmit user-specific data to and/or receive user-specific data from the BSs 110. In general, each UE 120 may be equipped with one or multiple antennas. The Nᵤ UEs 120 can have the same or different numbers of antennas.

The wireless communications network 100 may be a time division duplex (TDD) system or a frequency division duplex (FDD) system. For a TDD system, the downlink and uplink share the same frequency band. For an FDD system, the downlink and uplink use different frequency bands. The wireless communications network 100 may also utilize a single carrier or multiple carriers for transmission. Each UE 120 may be equipped with a single antenna (e.g., to keep costs down) or multiple antennas (e.g., where the additional cost can be supported).

A network controller 130 (also sometimes referred to as a “system controller”) may be in communication with a set of BSs 110 and provide coordination and control for these BSs 110 (e.g., via a backhaul). In certain cases (e.g., in a 5G NR system), the network controller 130 may include a centralized unit (CU) and/or a distributed unit (DU). In certain aspects, the network controller 130 may be in communication with a core network 132 (e.g., a 5G Core Network (5GC)), which provides various network functions such as Access and Mobility Management, Session Management, User Plane Function, Policy Control Function, Authentication Server Function, Unified Data Management, Application Function, Network Exposure Function, Network Repository Function, Network Slice Selection Function, etc.

In certain aspects of the present disclosure, the BSs 110 and/or the UEs 120 may include a frequency synthesizer implemented with a supply-side filter for a voltage-controlled oscillator (VCO) using at least one n-type metal-oxide-semiconductor (NMOS) transistor.

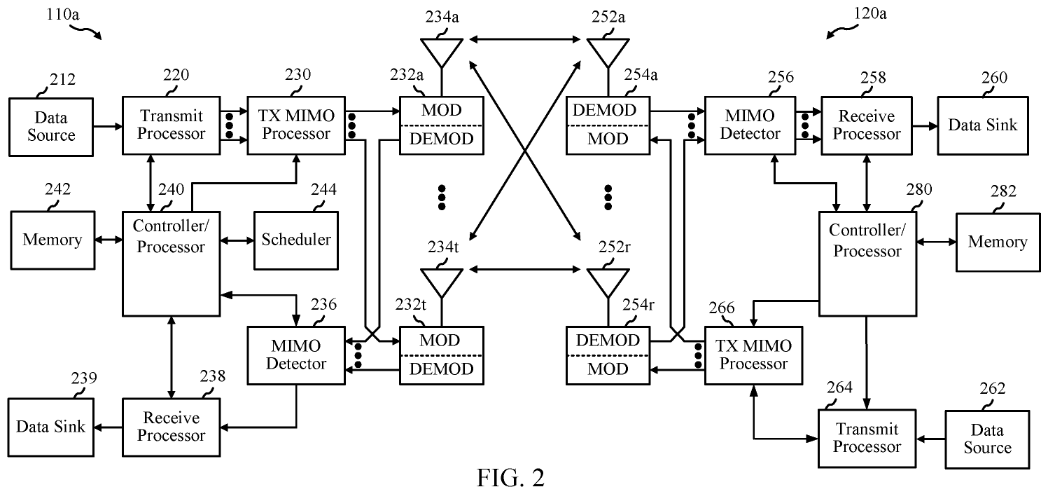

FIG. 2 illustrates example components of BS 110a and UE 120a (e.g., from the wireless communications network 100 of FIG. 1), in which aspects of the present disclosure may be implemented.

On the downlink, at the BS 110a, a transmit processor 220 may receive data from a data source 212, control information from a controller/processor 240, and/or possibly other data (e.g., from a scheduler 244). The various types of data may be sent on different transport channels. For example, the control information may be designated for the physical broadcast channel (PBCH), physical control format indicator channel (PCFICH), physical hybrid automatic repeat request (HARQ) indicator channel (PHICH), physical downlink control channel (PDCCH), group common PDCCH (GC PDCCH), etc. The data may be designated for the physical downlink shared channel (PDSCH), etc. A medium access control (MAC)-control element (MAC-CE) is a MAC layer communication structure that may be used for control command exchange between wireless nodes. The MAC-CE may be carried in a shared channel such as a PDSCH, a physical uplink shared channel (PUSCH), or a physical sidelink shared channel (PSSCH).

The processor 220 may process (e.g., encode and symbol map) the data and control information to obtain data symbols and control symbols, respectively. The transmit processor 220 may also generate reference symbols, such as for the primary synchronization signal (PSS), secondary synchronization signal (SSS), PBCH demodulation reference signal (DMRS), and channel state information reference signal (CSI-RS).

A transmit (TX) multiple-input, multiple-output (MIMO) processor 230 may perform spatial processing (e.g., precoding) on the data symbols, the control symbols, and/or the reference symbols, if applicable, and may provide output symbol streams to the modulators (MODs) in transceivers 232a-232t. Each modulator in transceivers 232a-232t may process a respective output symbol stream (e.g., for orthogonal frequency division multiplexing (OFDM), etc.) to obtain an output sample stream. Each of the transceivers 232a-232t may further process (e.g., convert to analog, amplify, filter, and upconvert) the output sample stream to obtain a downlink signal. Downlink signals from the transceivers 232a-232t may be transmitted via the antennas 234a-234t, respectively.

At the UE 120a, the antennas 252a-252r may receive the downlink signals from the BS 110a and may provide received signals to the transceivers 254a-254r, respectively. The transceivers 254a-254r may condition (e.g., filter, amplify, downconvert, and digitize) a respective received signal to obtain input samples. Each demodulator (DEMOD) in the transceivers 232a-232t may further process the input samples (e.g., for OFDM, etc.) to obtain received symbols. A MIMO detector 256 may obtain received symbols from all the demodulators in transceivers 254a-254r, perform MIMO detection on the received symbols if applicable, and provide detected symbols. A receive processor 258 may process (e.g., demodulate, deinterleave, and decode) the detected symbols, provide decoded data for the UE 120a to a data sink 260, and provide decoded control information to a controller/processor 280.

On the uplink, at UE 120a, a transmit processor 264 may receive and process data (e.g., for the physical uplink shared channel (PUSCH)) from a data source 262 and control information (e.g., for the physical uplink control channel (PUCCH)) from the controller/processor 280. The transmit processor 264 may also generate reference symbols for a reference signal (e.g., the sounding reference signal (SRS)). The symbols from the transmit processor 264 may be precoded by a TX MIMO processor 266 if applicable, further processed by the modulators (MODs) in transceivers 254a-254r (e.g., for single-carrier frequency division multiplexing (SC-FDM), etc.), and transmitted to the BS 110a. At the BS 110a, the uplink signals from the UE 120a may be received by the antennas 234, processed by the demodulators in transceivers 232a-232t, detected by a MIMO detector 236 if applicable, and further processed by a receive processor 238 to obtain decoded data and control information sent by the UE 120a. The receive processor 238 may provide the decoded data to a data sink 239 and the decoded control information to the controller/processor 240.

The memories 242 and 282 may store data and program codes for BS 110a and UE 120a, respectively. The memories 242 and 282 may also interface with the controllers/processors 240 and 280, respectively. A scheduler 244 may schedule UEs for data transmission on the downlink and/or uplink.

In certain aspects of the present disclosure, the transceivers 232 and/or the transceivers 254 may include a frequency synthesizer implemented with a supply-side filter for a VCO using at least one NMOS transistor.

NR may utilize orthogonal frequency division multiplexing (OFDM) with a cyclic prefix (CP) on the uplink and downlink. NR may support half-duplex operation using time division duplexing (TDD). OFDM and single-carrier frequency division multiplexing (SC-FDM) partition the system bandwidth into multiple orthogonal subcarriers, which are also commonly referred to as tones, bins, etc. Each subcarrier may be modulated with data. Modulation symbols may be sent in the frequency domain with OFDM and in the time domain with SC-FDM. The spacing between adjacent subcarriers may be fixed, and the total number of subcarriers may be dependent on the system bandwidth. The system bandwidth may also be partitioned into subbands. For example, a subband may cover multiple resource blocks (RBs).

### Example RF Transceiver

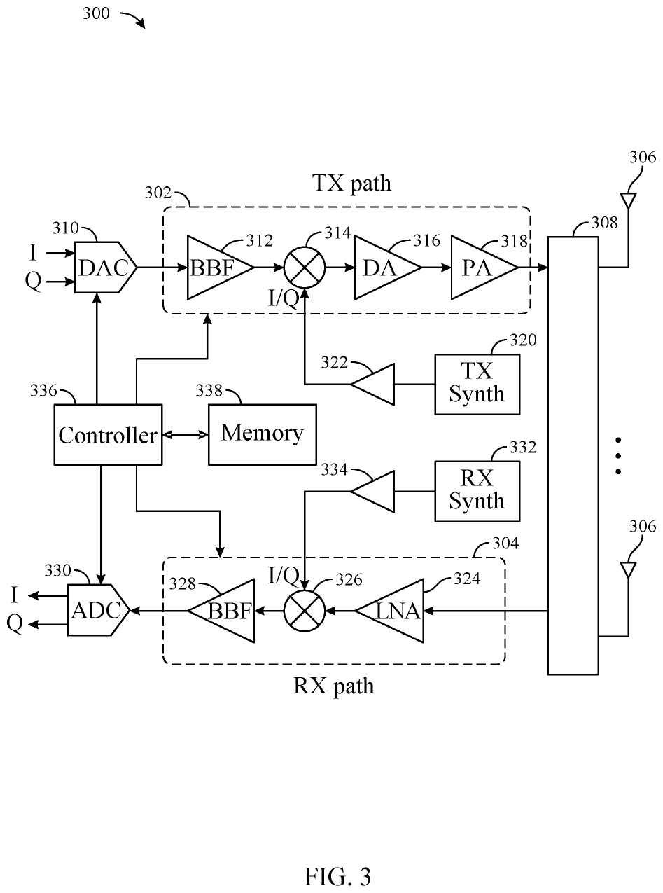

FIG. 3 is a block diagram of an example radio frequency (RF) transceiver circuit 300, in accordance with certain aspects of the present disclosure. The RF transceiver circuit 300 includes at least one transmit (TX) path 302 (also known as a “transmit chain”) for transmitting signals via one or more antennas 306 and at least one receive (RX) path 304 (also known as a “receive chain”) for receiving signals via the antennas 306. When the TX path 302 and the RX path 304 share an antenna 306, the paths may be connected with the antenna via an interface 308, which may include any of various suitable RF devices, such as a switch, a duplexer, a diplexer, a multiplexer, and the like.

Receiving in-phase (I) and/or quadrature (Q) baseband analog signals from a digital-to-analog converter (DAC) 310, the TX path 302 may include a baseband filter (BBF) 312, a mixer 314, a driver amplifier (DA) 316, and a power amplifier (PA) 318. The BBF 312, the mixer 314, the DA 316, and the PA 318 may be included in a radio frequency integrated circuit (RFIC). For certain aspects, the PA 318 may be external to the RFIC.

The BBF 312 filters the baseband signals received from the DAC 310, and the mixer 314 mixes the filtered baseband signals with a transmit local oscillator (LO) signal to convert the baseband signal of interest to a different frequency (e.g., upconvert from baseband to a radio frequency). This frequency-conversion process produces the sum and difference frequencies between the LO frequency and the frequencies of the baseband signal of interest. The sum and difference frequencies are referred to as the “beat frequencies.” The beat frequencies are typically in the RF range, such that the signals output by the mixer 314 are typically RF signals, which may be amplified by the DA 316 and/or by the PA 318 before transmission by the antenna(s) 306. While one mixer 314 is illustrated, several mixers may be used to upconvert the filtered baseband signals to one or more intermediate frequencies and to thereafter upconvert the intermediate frequency (IF) signals to a frequency for transmission.

The RX path 304 may include a low noise amplifier (LNA) 324, a mixer 326, and a baseband filter (BBF) 328. The LNA 324, the mixer 326, and the BBF 328 may be included in one or more RFICs, which may or may not be the same RFIC that includes the TX path components. RF signals received via the antenna(s) 306 may be amplified by the LNA 324, and the mixer 326 mixes the amplified RF signals with a receive local oscillator (LO) signal to convert the RF signal of interest to a different baseband frequency (e.g., downconvert). The baseband signals output by the mixer 326 may be filtered by the BBF 328 before being converted by an analog-to-digital converter (ADC) 330 to digital I and/or Q signals for digital signal processing.

Certain transceivers may employ frequency synthesizers with a variable-frequency oscillator (e.g., a voltage-controlled oscillator (VCO) or a digitally controlled oscillator (DCO)) to generate a stable, tunable LO with a particular tuning range. Thus, the transmit LO may be produced by a TX frequency synthesizer 320, which may be buffered or amplified by amplifier 322 before being mixed with the baseband signals in the mixer 314. Similarly, the receive LO may be produced by an RX frequency synthesizer 332, which may be buffered or amplified by amplifier 334 before being mixed with the RF signals in the mixer 326. For certain aspects, a single frequency synthesizer may be used for both the TX path 302 and the RX path 304. In some aspects, the frequency synthesizer 320 or frequency synthesizer 332 may be implemented with a supply-side filter for a VCO using at least one NMOS transistor.

A controller 336 (e.g., controller/processor 280 in FIG. 2) may direct the operation of the RF transceiver circuit 300A, such as transmitting signals via the TX path 302 and/or receiving signals via the RX path 304. The controller 336 may be a processor, a digital signal processor (DSP), an application-specific integrated circuit (ASIC), a field-programmable gate array (FPGA) or other programmable logic device (PLD), discrete gate or transistor logic, discrete hardware components, or any combination thereof. A memory 338 (e.g., memory 282 in FIG. 2) may store data and/or program codes for operating the RF transceiver circuit 300. The controller 336 and/or the memory 338 may include control logic (e.g., complementary metal-oxide-semiconductor (CMOS) logic).

While FIGS. 1-3 provide wireless communications as an example application in which certain aspects of the present disclosure may be implemented to facilitate understanding, certain aspects described herein may be used for any of various other suitable systems. For example, the techniques described herein to generate an oscillating signal may be applied to any suitable communication system such as a wired communication system.

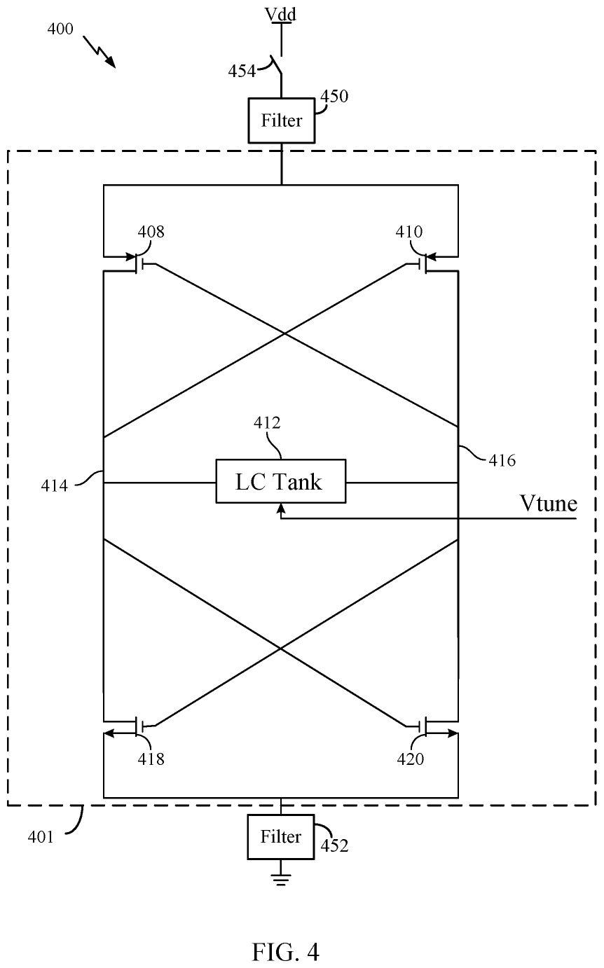

FIG. 4 illustrates an example oscillating circuit 400 including a VCO 401, in accordance with certain aspects of the present disclosure. The VCO 401 may be used to implement the synthesizer 320 or synthesizer 332 described with respect to FIG. 3. As shown, the VCO 401 may include cross-coupled p-type metal-oxide-semiconductor (PMOS) transistors 408, 410 (e.g., transconductance (gm) transistors). Sources of transistors 408, 410 are coupled to a voltage rail (Vdd). In some cases, a filter 450 may be coupled between the sources of the transistors 408, 410 and Vdd for harmonic signal attenuation. For example, the filter 450 may be a notch filter configured to attenuate a frequency that is twice the oscillating frequency of the VCO 401, reducing the second harmonic signal of the VCO. In some aspects, a switch 454 may be coupled between Vdd and the filter 450. The switch 454 may be controlled to enable or disable (e.g., power on or power off) the VCO 401. In lieu of the switch 454, a current source may be used in some implementations.

A gate of transistor 408 may be coupled to an output node 416 of the VCO, and a gate of transistor 410 may be coupled to an output node 414, as shown. A tank circuit 412 (e.g., inductor-capacitor (LC) tank circuit) may be coupled between the output nodes 414, 416. A tuning voltage (Vtune) may be provided to the tank circuit 412 to adjust the oscillating frequency of the VCO.

As shown, the VCO 401 also includes cross-coupled n-type metal-oxide-semiconductor (NMOS) transistors 418, 420 (e.g., transconductance (gm) transistors). Sources of transistors 418, 420 are coupled to a reference potential node (e.g., electric ground). In some aspects, a filter 452 may be coupled between the sources of the transistors 418, 420 and the reference potential node for harmonic signal attenuation. For example, the filter 452 may be a notch filter configured to attenuate a frequency that is twice the oscillating frequency of the VCO 401, reducing the second harmonic signal of the VCO.

### Example Techniques for Harmonic Tuning

P-type metal-oxide-semiconductor (PMOS) transistors have a higher on-resistance (R_{ON}) than n-type metal-oxide-semiconductor (NMOS) transistors, given the same dimensions. In some implementations, PMOS transistors may be used to adjust a capacitance of a capacitor bank of a supply-side filter (e.g., filter 450 described with respect to FIG. 4). The higher R_{ON} of the PMOS transistors may lead to a degradation in the amount of second harmonic noise reduction (e.g., due to the resultant lower quality factor (Q) of the filter). In some implementations, a voltage rail (Vdd) of the VCO may be reduced to increase reliability and/or reduce power consumption, further increasing R_{ON} for both PMOS and NMOS transistors used to implement respective filters 450, 452 if the transistors are implemented as thick-oxide devices. As a result, quality factor specifications for the VCO may not be met. Certain aspects of the present disclosure are directed towards an implementation of the supply-side filter (e.g., filter 450) with NMOS transistors having a lower R_{ON} than PMOS transistors. Moreover, the NMOS transistors used to implement the filter 450 (e.g., in some aspects, filter 452) may be implemented as thin-oxide devices, further reducing the R_{ON} and the resultant Q of the filter.

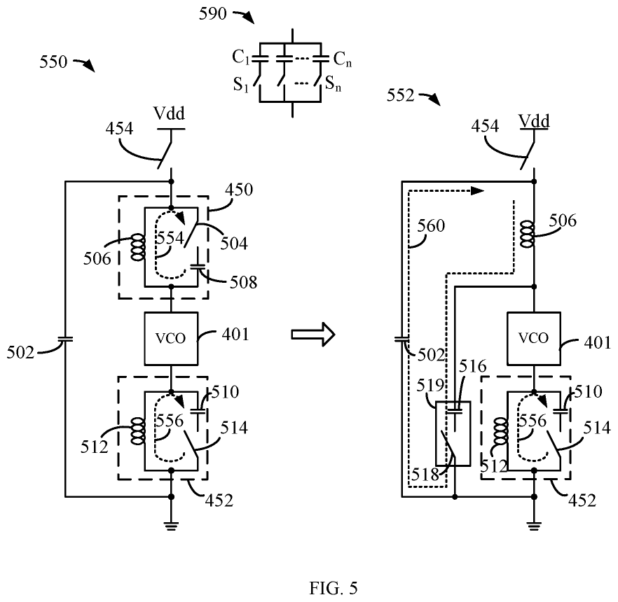

FIG. 5 illustrates example implementations of filters for a VCO 401, in accordance with certain aspects of the present disclosure. As shown, for oscillating circuit 550, the filter 450 may be implemented using an inductive element 506 coupled in parallel with a capacitor bank. As shown in diagram 590, a capacitor bank may include capacitive elements C₁-Cₙ (e.g., n being any positive integer) each selectively coupled between terminals of the capacitor bank via a respective switch S₁-Sₙ. As used herein, a capacitor circuit may refer to one or more capacitive elements, such as the capacitive elements C₁-Cₙ, and a switch circuit may refer to one or more switches, such as switches S₁-Sₙ. The filter 450 may include the inductive element 506 in parallel with a capacitor bank where the capacitor bank includes a capacitor circuit 508 coupled to switch circuit 504 as described.

As shown, the filter 450 creates a current loop 554, including the capacitor bank and the inductive element to implement the frequency response of the notch filter 450. Similarly, the filter 452 may be implemented using an inductive element 512 coupled in parallel with a capacitor bank, including a capacitor circuit 510 coupled to a switch circuit 514. As shown, the filter 452 creates a current loop 556, including the capacitor bank and the inductive element to implement the frequency response of the notch filter 452.

In some aspects, a bypass capacitive element 502 may be coupled between the voltage rail Vdd and the reference potential node, as shown. The bypass capacitive element 502 serves as a noise filter for the VCO 401 by providing a low-impedance path for high-frequency noise from Vdd to the reference potential node (e.g., electric ground).

As described herein, the switches of the switch circuit 504 of the filter 450 on the supply-side may be implemented using PMOS transistors, and the R_{ON} of the PMOS transistors may result in degradation of the filter quality factor. Thus, to implement the supply-side filter 450 with NMOS transistors having a lower R_{ON} as compared to PMOS transistors and improve the filter Q, the oscillating circuit 552 may be used. For oscillating circuit 552, the switches of the switch circuit 514 of the filter 452 may be implemented with thin-oxide NMOS transistors, providing a reduced R_{ON} as compared to using thick-oxide NMOS transistors, resulting in an increased Q.

In some aspects, the supply-side filter may be implemented using the inductive element 506 and a capacitor bank 519 including a capacitor circuit 516 coupled to a switch circuit 518. The capacitor bank 519 may be coupled between the inductive element 506 and the reference potential node, as shown.

With the supply-side filter of oscillating circuit 552, the switches of the switch circuit 518 for the capacitor bank may be implemented using NMOS transistors having a lower R_{ON} than the PMOS transistors used to implement the filter 450 of oscillating circuit 550, providing a higher Q for the supply-side filter. The current loop 560 for the supply-side filter may include the bypass capacitive element 502. Moreover, the switches of the switch circuit 518 may be implemented using thin-oxide NMOS transistors, further increasing the Q of the filter.

Using the oscillating circuit 552 may degrade the quality of the inductive element for the supply-side filter due to the increased routing distance associated with the current loop 560 (e.g., as compared to current loop 554 of filter 450) and the bypass capacitive element 502 being part of the loop 560. However, using thin-oxide NMOS transistors increases the overall Q of the supply-side filter of the oscillating circuit 552 compared to oscillating circuit 550.

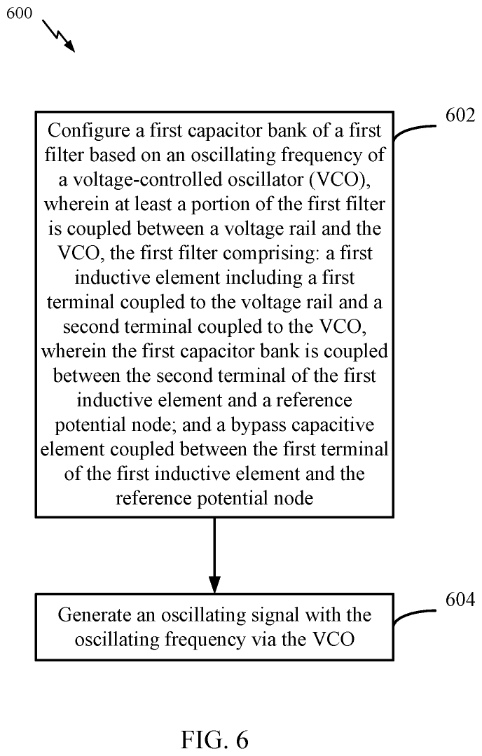

FIG. 6 is a flow diagram illustrating example operations 600 for oscillating signal generation, in accordance with certain aspects of the present disclosure. The operations 600 may be performed, for example, by an oscillating circuit such as the oscillating circuit 552.

At block 602, the oscillating circuit configures a first capacitor bank (e.g., capacitor bank 519) of a first filter based on an oscillating frequency of a VCO. In some aspects, the first filter may include a notch filter. At least a portion of the first filter may be coupled between a voltage rail and the VCO (e.g., VCO 401 of FIG. 5). The first filter may include a first inductive element (e.g., inductive element 506) including a first terminal coupled to the voltage rail and a second terminal coupled to the VCO. The first capacitor bank may be coupled between the second terminal of the first inductive element and a reference potential node. The first filter may include a bypass capacitive element (e.g., capacitive element 502) coupled between the first terminal of the first inductive element and the reference potential node. At block 604, the oscillating circuit may generate an oscillating signal with the oscillating frequency via the VCO.

In some aspects, the first capacitor bank may include one or more switches (e.g., included as part of switching circuit 518 and corresponding to switches S₁ to Sₙ). The first capacitor bank may also include one or more capacitive elements (e.g., included as part of capacitor circuit 516 and corresponding to switches C₁ to Cₙ), each of the one or more capacitive elements being selectively coupled between terminals of the capacitor bank via a respective one of the one or more switches. In some aspects, the one or more switches comprise one or more NMOS transistors. The one or more NMOS transistors may include thin-oxide NMOS transistors.

In some aspects, the oscillating circuit may configure a second capacitor bank (e.g., including capacitor circuit 510 and switch circuit 514) of a second filter (e.g., filter 452 of FIG. 5) coupled between the VCO and the reference potential node based on the oscillating frequency of the VCO. The second filter may include a second inductive element (e.g., inductive element 512) coupled in parallel with the second capacitor bank.

In some aspects, the second capacitor bank may include one or more switches (e.g., included as part of switching circuit 514 and corresponding to switches S₁ to Sₙ). The second capacitor bank may also include one or more capacitive elements (e.g., included as part of capacitor circuit 510 and corresponding to switches C₁ to Cₙ), each of the one or more capacitive elements being selectively coupled between terminals of the second capacitor bank via a respective one of the one or more switches. In some aspects, the one or more switches comprise one or more NMOS transistors. The one or more NMOS transistors may include thin-oxide NMOS transistors.

### Example Aspects

In addition to the various aspects described above, specific combinations of aspects are within the scope of the present disclosure, some of which are detailed below:

Aspect 1: An apparatus for oscillating signal generation, comprising: a voltage-controlled oscillator (VCO); and a first filter coupled to the VCO, wherein the first filter comprises: a first inductive element including a first terminal coupled to a voltage rail and a second terminal coupled to the VCO; a first capacitor bank coupled between the second terminal of the first inductive element and a reference potential node; and a bypass capacitive element coupled between the first terminal of the first inductive element and the reference potential node.

Aspect 2: The apparatus of Aspect 1, further comprising a switch or current source coupled between the voltage rail and the first terminal of the first inductive element.

Aspect 3: The apparatus of Aspect 1 or 2, wherein the first capacitor bank comprises: one or more switches; and one or more capacitive elements, each of the one or more capacitive elements being selectively coupled between terminals of the first capacitor bank via a respective one of the one or more switches.

Aspect 4: The apparatus of Aspect 3, wherein the one or more switches comprise one or more n-type metal-oxide-semiconductor (NMOS) transistors.

Aspect 5: The apparatus of Aspect 4, wherein the one or more NMOS transistors comprise thin-oxide NMOS transistors.

Aspect 6: The apparatus according to any of Aspects 1-5, wherein the first filter comprises a notch filter.

Aspect 7: The apparatus according to any of Aspects 1-6, further comprising a second filter coupled between the VCO and the reference potential node.

Aspect 8: The apparatus of Aspect 7, wherein the second filter comprises a second inductive element coupled in parallel with a second capacitor bank.

Aspect 9: The apparatus of Aspect 8, wherein the second capacitor bank comprises: one or more switches; and one or more capacitive elements, each of the one or more capacitive elements being selectively coupled between terminals of the second capacitor bank via a respective one of the one or more switches.

Aspect 10: The apparatus of Aspect 9, wherein the one or more switches comprise one or more n-type metal-oxide-semiconductor (NMOS) transistors.

Aspect 11: The apparatus of Aspect 10, wherein the one or more NMOS transistors comprise thin-oxide NMOS transistors.

Aspect 12: The apparatus according to any of Aspects 7-11, wherein the second filter comprises a notch filter.

Aspect 13: The apparatus according to any of Aspects 7-12, wherein the second filter is configured to attenuate a signal with a frequency that is twice an oscillating frequency of the VCO.

Aspect 14: The apparatus according to any of Aspects 1-13, wherein the first filter is configured to attenuate a signal with a frequency that is twice an oscillating frequency of the VCO.

Aspect 15: A method for oscillating signal generation, comprising: configuring a first capacitor bank of a first filter based on an oscillating frequency of a voltage-controlled oscillator (VCO), wherein at least a portion of the first filter is coupled between a voltage rail and the VCO, the first filter comprising: a first inductive element including a first terminal coupled to the voltage rail and a second terminal coupled to the VCO, wherein the first capacitor bank is coupled between the second terminal of the first inductive element and a reference potential node; and a bypass capacitive element coupled between the first terminal of the first inductive element and the reference potential node; and generating an oscillating signal with the oscillating frequency via the VCO.

Aspect 16: The method of Aspect 15, wherein the first capacitor bank comprises: one or more switches; and one or more capacitive elements, each of the one or more capacitive elements being selectively coupled between terminals of the first capacitor bank via a respective one of the one or more switches.

Aspect 17: The method of Aspect 16, wherein the one or more switches comprise one or more n-type metal-oxide-semiconductor (NMOS) transistors.

Aspect 18: The method of Aspect 17, wherein the one or more NMOS transistors comprise thin-oxide NMOS transistors.

Aspect 19: The method according to any of Aspects 15-18, wherein the first filter comprises a notch filter.

Aspect 20: The method according to any of Aspects 15-19, further comprising configuring a second capacitor bank of a second filter coupled between the VCO and the reference potential node based on the oscillating frequency of the VCO.

Aspect 21: The method of Aspect 20, wherein the second filter comprises a second inductive element coupled in parallel with the second capacitor bank.

Aspect 22: The method of Aspect 20 or 21, wherein the second capacitor bank comprises: one or more switches; and one or more capacitive elements, each of the one or more capacitive elements being selectively coupled between terminals of the second capacitor bank via a respective one of the one or more switches.

Aspect 23: The method of Aspect 22, wherein the one or more switches comprise one or more n-type metal-oxide-semiconductor (NMOS) transistors.

Aspect 24: The method of Aspect 23, wherein the one or more NMOS transistors comprise thin-oxide NMOS transistors.

Aspect 25: The method according to any of Aspects 20-24, wherein the second filter comprises a notch filter.

Aspect 26: A wireless device comprising: one or more antennas; a transmitter or a receiver coupled to the one or more antennas and including a frequency synthesizer, wherein the frequency synthesizer includes a voltage-controlled oscillator (VCO); and a filter coupled to the VCO, wherein the filter comprises: an inductive element including a first terminal coupled to a voltage rail and a second terminal coupled to the VCO; a capacitor bank coupled between the second terminal and a reference potential node; and a bypass capacitive element coupled between the first terminal of the inductive element and the reference potential node.

The above description provides examples, and is not limiting of the scope, applicability, or examples set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method which is practiced using other structure, functionality, or structure and functionality in addition to, or other than, the various aspects of the disclosure set forth herein. It should be understood that any aspect of the disclosure disclosed herein may be embodied by one or more elements of a claim.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes, and variations may be made in the arrangement, operation, and details of the methods and apparatus described above without departing from the scope of the claims.

1. An apparatus for oscillating signal generation, comprising:
a voltage-controlled oscillator (VCO); and
a first filter coupled to the VCO, wherein the first filter comprises:
a first inductive element including a first terminal coupled to a voltage rail and a second terminal coupled to the VCO;
a first capacitor bank coupled between the second terminal of the first inductive element and a reference potential node; and
a bypass capacitive element coupled between the first terminal of the first inductive element and the reference potential node.

2. The apparatus of claim 1, further comprising a switch or current source coupled between the voltage rail and the first terminal of the first inductive element.

3. The apparatus of claim 1, wherein the first capacitor bank comprises:
one or more switches; and
one or more capacitive elements, each of the one or more capacitive elements being selectively coupled between terminals of the first capacitor bank via a respective one of the one or more switches.

4. The apparatus of claim 3, wherein the one or more switches comprise one or more n-type metal-oxide-semiconductor (NMOS) transistors.

5. The apparatus of claim 4, wherein the one or more NMOS transistors comprise thin-oxide NMOS transistors.

6. The apparatus of claim 1, wherein the first filter comprises a notch filter.

7. The apparatus of claim 1, further comprising a second filter coupled between the VCO and the reference potential node.

8. The apparatus of claim 7, wherein the second filter comprises a second inductive element coupled in parallel with a second capacitor bank.

9. The apparatus of claim 8, wherein the second capacitor bank comprises:
one or more switches; and
one or more capacitive elements, each of the one or more capacitive elements being selectively coupled between terminals of the second capacitor bank via a respective one of the one or more switches.

10. The apparatus of claim 9, wherein the one or more switches comprise one or more n-type metal-oxide-semiconductor (NMOS) transistors.

11. The apparatus of claim 10, wherein the one or more NMOS transistors comprise thin-oxide NMOS transistors.

12. The apparatus of claim 7, wherein the second filter comprises a notch filter.

13. The apparatus of claim 7, wherein the second filter is configured to attenuate a signal with a frequency that is twice an oscillating frequency of the VCO.

14. The apparatus of claim 1, wherein the first filter is configured to attenuate a signal with a frequency that is twice an oscillating frequency of the VCO.

15. A method for oscillating signal generation, comprising:
configuring a first capacitor bank of a first filter based on an oscillating frequency of a voltage-controlled oscillator (VCO), wherein at least a portion of the first filter is coupled between a voltage rail and the VCO, the first filter comprising:
a first inductive element including a first terminal coupled to the voltage rail and a second terminal coupled to the VCO, wherein the first capacitor bank is coupled between the second terminal of the first inductive element and a reference potential node; and
a bypass capacitive element coupled between the first terminal of the first inductive element and the reference potential node; and
generating an oscillating signal with the oscillating frequency via the VCO.

16. The method of claim 15, wherein the first capacitor bank comprises:
one or more switches; and
one or more capacitive elements, each of the one or more capacitive elements being selectively coupled between terminals of the first capacitor bank via a respective one of the one or more switches.

17. The method of claim 16, wherein the one or more switches comprise one or more n-type metal-oxide-semiconductor (NMOS) transistors.

18. The method of claim 17, wherein the one or more NMOS transistors comprise thin-oxide NMOS transistors.

19. The method of claim 15, wherein the first filter comprises a notch filter.

20. A wireless device comprising:
one or more antennas;
a transmitter or a receiver coupled to the one or more antennas and including a frequency synthesizer, wherein the frequency synthesizer includes a voltage-controlled oscillator (VCO); and
a filter coupled to the VCO, wherein the filter comprises:
an inductive element including a first terminal coupled to a voltage rail and a second terminal coupled to the VCO;
a capacitor bank coupled between the second terminal and a reference potential node; and
a bypass capacitive element coupled between the first terminal of the inductive element and the reference potential node.
